(19) United States
(12) Patent Application Publication
(10) Pub. No.: US 2007/0052100 A1
(43) Pub. Date: Mar. 8, 2007

(54) Spring clip for a portable electronic device

(75) Inventor: Barry J. Paul Bellinger, Newbury (GB)

Correspondence Address: HARRINGTON & SMITH, LLP, 4 RESEARCH DRIVE, SHELTON, CT, 06484-6212, US

(73) Assignee: Nokia Corporation

(21) Appl. No.: 11/221,651

(22) Filed: Sep. 7, 2005

(51) Int. Cl. H01L 23/48

(52) U.S. Cl. 257/758; 257/727; 257/678

(57) ABSTRACT

A portable electronic device spring clip including a first retention section adapted to attach the spring clip to a framework; a second retention section adapted to be located at a top side of a metal cover frame of a display module of a portable electronic device; a first contact section adapted to electrically connect to a printed wiring board (PWB); and a second contact section adapted to electrically connect to the metal cover frame of the display module. The spring clip is adapted to electrically connect the metal cover frame of the display module to the PWB. The spring clip is adapted to mechanically retain the display module to the PWB when the framework is connected to the PWB.

### BACKGROUND OF THE INVENTION

1. Field of the Invention

The invention relates to a portable electronic device and, more particularly, to a spring clip used in a portable electronic device.

2. Brief Description of Prior Developments

In a conventional mobile telephone a liquid crystal display (LCD) module is provided which is mechanically and electrically connected to a printed wiring board (PWB) of the telephone. The LCD display module is supplied with a metal cover frame. The display module is assembled onto a resin non-conductive polymer framework. To meet electromagnetic compatibility (EMC) requirements for the telephone, a suitable number of grounding points are required between the display module and the PWB. The display module assembly requires that it be held in place after assembly and transportation with the framework for final assembly into the telephone.

The problem of EMC grounding was previously solved by several methods. EMC grounding methods used in the past included spring fingers soldered to a PWB main board, pressing upwards underneath the LCD display module metal cover, or conductive foam pads stuck to the PWB main board. Retention of the LCD display module was by a metal cover shield over the LCD display module held in position by screws to a resin non-conductive polymer framework. Or the resin non-conductive polymer framework had interference features that supported the LCD display module in place; temporarily until an outer cover of the telephone was secured by screws. These conventional types of connections are not well suited for smaller size portable electronic devices.

There is a desire to provide a new type of mechanical connection of a display module to a PWB which can be accommodated in a smaller size portable electronic device. There is a desire to simplify mechanical and electrical connections between a display module and a PWB in a portable electronic device for faster and less costly manufacture, as well as a more robust design.

### SUMMARY OF THE INVENTION

In accordance with one aspect of the invention, a portable electronic device spring clip is provided including a first retention section adapted to attach the spring clip to a framework; a second retention section adapted to be located at a top side of a metal cover frame of a display module of a portable electronic device; a first contact section adapted to electrically connect to a printed wiring board (PWB); and a second contact section adapted to electrically connect to the metal cover frame of the display module. The spring clip is adapted to electrically connect the metal cover frame of the display module to the PWB. The spring clip is adapted to mechanically retain the display module to the PWB when the framework is connected to the PWB.

In accordance with another aspect of the invention, a display module mounting assembly for mounting a display module to a printed wiring board (PWB) in a portable electronic device is provided comprising a framework comprising a spring clip mounting area; and an electrically conductive spring clip connected to the framework at the spring clip mounting area. The spring clip comprises deflectable contact sections and a retention section. The deflectable contact sections are adapted to electrically contact the display module to the PWB. The retention section is adapted to clip onto the framework. The spring clip mounting area comprises at least one first recess for locating the retention section of the spring clip in the at least one first recess to thereby clip the spring clip onto the framework, and at least one second recess providing an open area within the framework for allowing the deflectable contact sections of the spring clip to deflect into when the deflectable contact sections make contact with the display module and the PWB.

In accordance with one method of the invention, a method of assembling a portable electronic device is provided comprising clipping electrically conductive spring clips onto a framework; inserting a display module into a receiving area of the framework, wherein the spring clips make electrical contact with the display module at the receiving area and form retention lips above a top surface of the display module; and attaching the framework to a printed wiring board (PWB), wherein the display module is mechanically captured by the retention lips and contact arms of the spring clips, and wherein the spring clips make electrical contact with the PWB to thereby electrically connect the display module to the PWB.

### BRIEF DESCRIPTION OF THE DRAWINGS

The foregoing aspects and other features of the invention are explained in the following description, taken in connection with the accompanying drawings, wherein:

FIG. 1 is a front view of a mobile telephone incorporating features of the invention;

FIG. 2 is a front view of a display module and mounting assembly used in the telephone shown in FIG. 1;

FIG. 3 is an enlarged partial perspective view of the framework and one of the spring clips of the mounting assembly shown in FIG. 2;

FIG. 4 is a perspective view of the spring clip shown in FIG. 3;

FIG. 5 is a perspective view of the spring clip shown in FIG. 4 taken from a different direction;

FIG. 6 is a side view of the spring clip shown in FIGS. 3-5;

FIG. 7 is an enlarged partial perspective view of the spring clip and the framework shown in FIG. 3 taken from a different direction; and

FIG. 8 is a perspective view of the printed wiring board (PWB), display module, and spring clip, without showing the framework, showing the electrical connection made by the spring clip.

### DETAILED DESCRIPTION OF THE PREFERRED EMBODIMENT

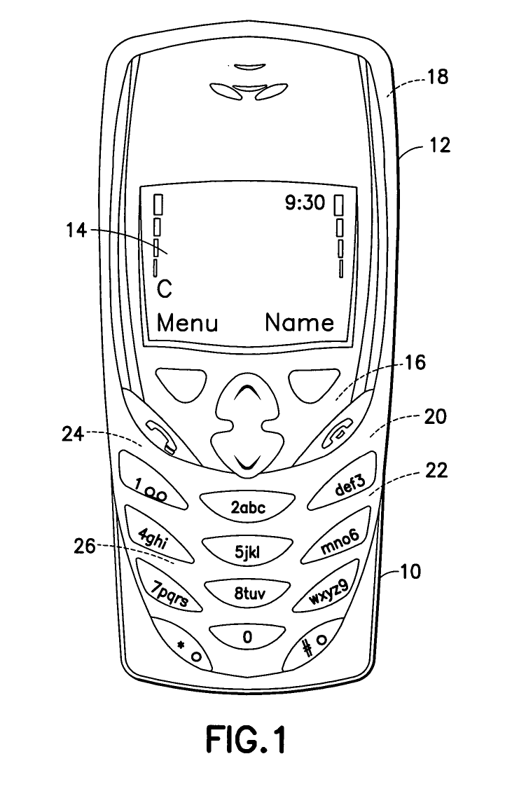

Referring to FIG. 1, there is shown a front view of a portable electronic device 10 incorporating features of the invention. Although the invention will be described with reference to the exemplary embodiment shown in the drawings, it should be understood that the invention can be embodied in many alternate forms of embodiments. In addition, any suitable size, shape or type of elements or materials could be used.

The device 10 comprises a mobile telephone or terminal. However, features of the invention could be used in any suitable type of portable electronic device, such as a personal data assistant (PDA), an electronic gaming device, a mobile communicator, a music player, etc. In the embodiment shown, the terminal 10 comprises a housing 12, a display module 14, a printed wiring board (PWB) or printed circuit board 16, an antenna 18, a transceiver 20, a mass memory 22, a program memory 24, and a controller 26. The terminal 10 obviously comprises other components. For example, in a mobile telephone or mobile communicator the terminal 10 comprises a user interface such as a touch screen or keys, a battery, a microphone and a speaker or sound transducer. The transceiver 20 and antenna 18 are adapted to communicate with a base station by means of a wireless link, such as a radio frequency link.

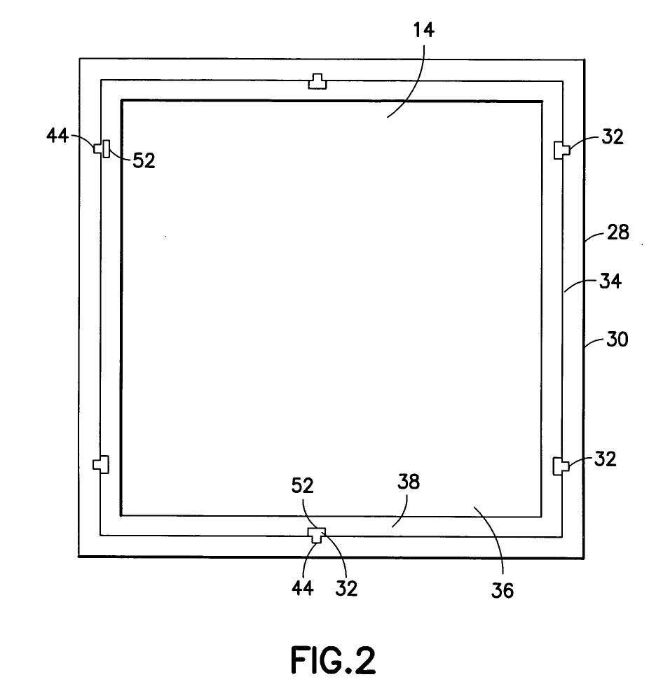

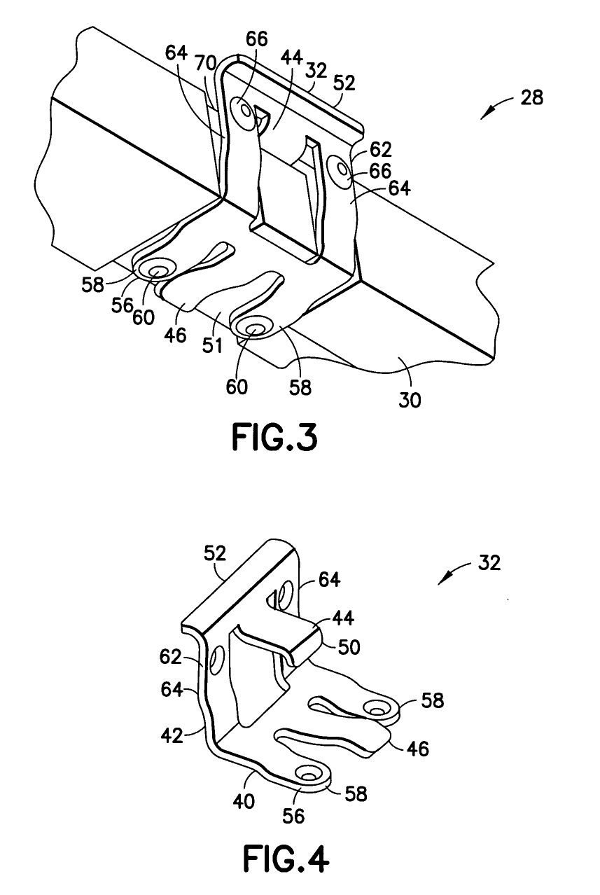

Referring also to FIGS. 2 and 3, the terminal 10 comprises a display module mounting assembly 28. The mounting assembly 28 connects the display module 14 to the PWB 16. The mounting assembly 28 generally comprises a framework 30 and electrically conductive spring clips 32. The framework 30 is comprised of an insulating material, such as a molded plastic or polymer material. The framework 30 has a general square or rectangular shape, but any suitable shape could be provided. In the embodiment shown, the framework forms a general ring shape with a display receiving area 34 inside the ring shape. The framework is preferably a one-piece member, but could be comprises of multiple members. The framework is adapted to be fixedly attached to the PWB at a stationary position by a suitable connection system, such as screws for example. However, any suitable connection system could be provided. If screws are used, the screws can be self-threading screws. The screws can be screwed through holes of the PWB and into holes of mounting bosses of a portable electronic device chassis cover for example.

The display module 14 comprises a LCD display 36 mounted inside a metal cover frame 38. The frame 38 is electrical connected to a ground of the display 36. The display 36 is electrically connected to electronics on the PWB 16, such as by wires or an electrical connector. The mounting assembly 28 is adapted to mechanically and electrically connect the display module 14 to the PWB 16. More specifically, the mounting assembly 28 mechanically attaches the display module 14 to the PWB 16 and, electrically connects the frame 38 of the display module to ground contacts on the PWB 16.

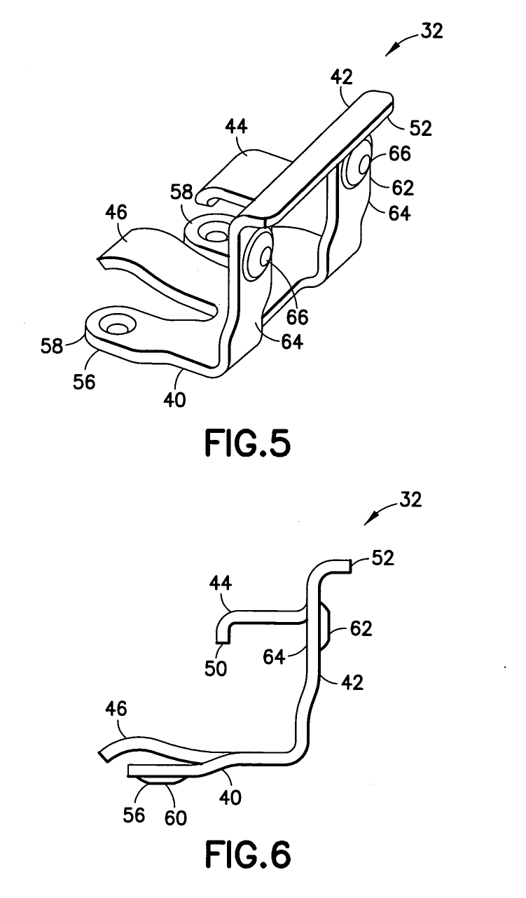

Referring also to FIGS. 4-6, each spring clip 32 comprises a one-piece metal member, such as a stamped and formed sheet metal member. However, in alternate embodiments each spring clip could be comprises of multiple members, and/or any suitable method of manufacturing the spring clips could be used. The spring clip 32 has a general L shaped profile as seen best in FIG. 6. The spring clip 32 has a bottom section 40 and a side section 42 which extends upward from the bottom section 40. A first retention section is formed by portions of both the bottom and side sections. In this embodiment the first retention section comprises two cantilevered arms 44, 46.

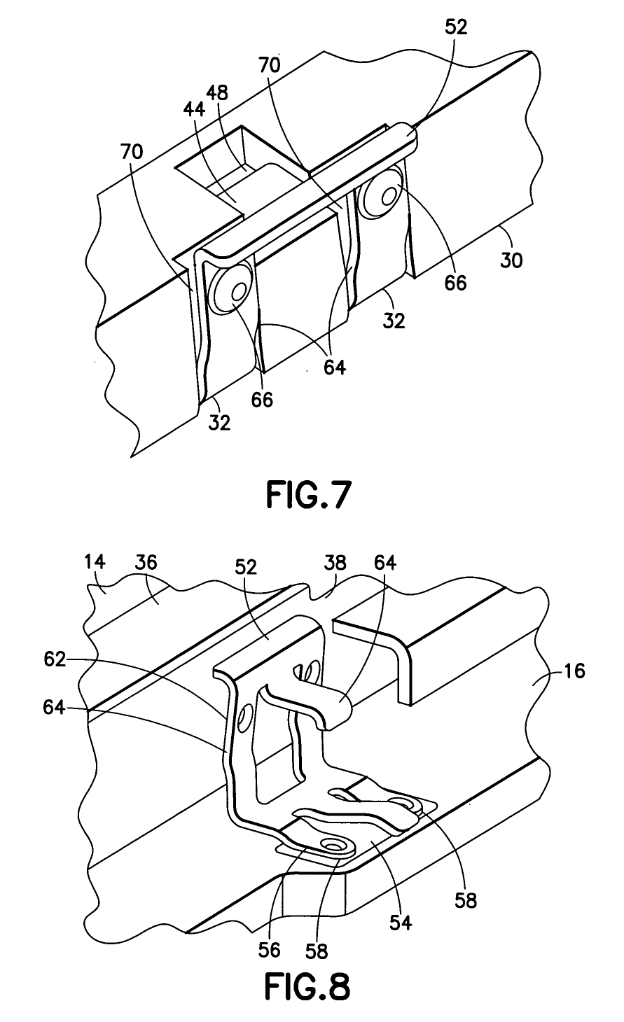

As seen best in FIGS. 3 and 7, the first retention section is adapted to attached the spring clip 32 to the framework 30. More specifically, the framework 30 has a mounting recess 48 on its top side for each spring clip. The arm 44 has a downward extending hook 50. The hook 50 is located in the mounting recess 48. The arm 46 is located in a mounting recess 51 on the bottom side of the framework. The arm 46 is a spring arm which, in combination with the arm 44, clips the spring clip on the framework. The side section 42 is located along the interior facing side of the framework; facing the display receiving area 34. The arms 44, 46 form two clip portions adapted to capture a portion of the framework therebetween.

A second retention section is formed by a lip 52 on the top of the side section 42. The lip 52 extends in a direction towards the display receiving area 34. The location of the lip 52 is such that, when the display module 14 is located in the display receiving area 34, the bottom side of the lip 52 contacts the top side of the metal cover frame 38. This forms a mechanical stop limit to upward movement of the display module in the receiving area 34.

The bottom section 40 includes a first contact section 56 for making electrical contact with the PWB. As seen best in FIG. 8, the PWB has ground contact pads 54. The first contact section 56 includes two cantilevered spring contact arms 58. The arms are located on opposite sides of the arm 46. However, in alternate embodiments more or less than two spring contact arms could be provided. The spring contact arms 58 extend downward slightly by a bent section. The spring contact arms 58 each include a protuberance 60, such as a stamped or coined dimple forming a bottom contact surface for contacting one of the ground contact pads 54 on the PWB. The spring contact arms 58 are able to deflect during connection of the mounting assemble 28 to the PWB. This gives a range taking capability and tolerance adjustment capability. Recess 51 provides an open area for the arms 58 to deflect into.

The spring clip 32 also includes a second contact section 62. The second contact section is located on the side section 42. The second contact section is provided for making electrical contact with the frame 38 of the display module 14. As seen best in FIG. 8, the frame 38 extends along the lateral sides of the display module 14. The second contact section 62 includes two spring contact arms 64. The arms are located on opposite sides of the arm 44. However, in alternate embodiments more or less than two spring contact arms could be provided. The spring contact arms 64 extend inward slightly by a bent section. The spring contact arms 64 each include a protuberance 66, such as a stamped or coined dimple forming a bottom contact surface for contacting the exterior lateral side 68 of the frame 38. In the embodiment shown, the protuberances form dome areas. The spring contact arms 64 are able to deflect during connection of the mounting assemble 28 to the display module 14. This gives a range taking capability and tolerance adjustment capability. Recessed 70 in the framework 30 are provided as open areas to allow the arms 64 to deflect into.

The protuberances 66 form a friction, pressure contact with the frame 38 of the display module 14. Because the spring clips 32 are located on multiple sides of the display module 14, this forms a frictional clamping of the display module inside the framework 30 at the sides of the display module. This clamping force, in combination with the lips 52, retain the display module inside the framework. The display module could also have a portion (not shown) for downward clamping of the display module to the frame work. In a preferred embodiment, when the framework is mounted to the PWB, the bottom of the display module is spaced from the PWB, such as with a gap of about 0.2 mm for example. Thus, the display module does not directly contact the PWB. Because the contact arms 58 can deflect slightly, the display module can float above the PWB.

The invention can comprise an LCD display retention spring grounding clip. Implementation of the spring clip can comprise engagement onto a non-conductive polymer framework, using special features on the non-conductive polymer framework to hold the spring clip in place, and allowing clearance recesses for the spring dome areas and retention features to make contact.

The spring clip can be made from commercial Stainless Steel and/or suitable non-corrosion authentic steels for example. A surface finish can be provided with Nickel and Gold plated to a 1 μm thickness, for example, for electrical conductivity. The spring clip can be cut and folded in several directions to form several domed contact pad areas and bent retention features. One set of dome contact pad areas can be used for pressing against the LCD display module. The other set of dome contact pad areas can be used for grounding to the PWB main board. In the embodiment described above, the bent retention features are of two forms; one bent form retains the spring clip to the resin non-conductive polymer framework, and the other bent form retains the LCD display module within the resin non-conductive polymer framework.

The reduction in design size on portable electronic devices does not support any previous methods of EMC grounding and retention. An alternative solution was made with the invention with use of small precision metal forming.

The invention can provide a method of using a spring clip which removes the need for separate grounding spring fingers soldered to a PWB main board, and removes the need for an over cover with screws to retain an LCD display module in place on the framework.

It should be understood that the foregoing description is only illustrative of the invention. Various alternatives and modifications can be devised by those skilled in the art without departing from the invention. Accordingly, the invention is intended to embrace all such alternatives, modifications and variances which fall within the scope of the appended claims.

What is claimed is:

1. A portable electronic device spring clip comprising:
a first retention section adapted to attach the spring clip to a framework;
a second retention section adapted to be located at a top side of a metal cover frame of a display module of a portable electronic device;
a first contact section adapted to electrically connect to a printed wiring board (PWB); and
a second contact section adapted to electrically connect to the metal cover frame of the display module,
wherein the spring clip is adapted to electrically connect the metal cover frame of the display module to the PWB, and wherein the spring clip is adapted to mechanically retain the display module to the PWB when the framework is connected to the PWB.

2. A portable electronic device spring clip as in claim 1 wherein the first retention section comprises two clip portions adapted to capture a portion of the framework therebetween.

3. A portable electronic device spring clip as in claim 1 wherein the second retention section comprises a retention lip sized and shaped to be located above a portion of a top surface of the display module when the display module is located in a receiving area of the framework.

4. A portable electronic device spring clip as in claim 1 wherein the first contact section comprises a first pair of deflectable contact arms.

5. A portable electronic device spring clip as in claim 4 wherein the contact arms each comprise a raised protuberance forming a contact surface.

6. A portable electronic device spring clip as in claim 4 wherein the second contact section comprises a second pair of deflectable contact arms.

7. A portable electronic device spring clip as in claim 6 wherein the second retention section comprises a retention lip sized and shaped to be located above a portion of a top surface of the display module when the display module is located in a receiving area of the framework, and wherein the retention lip connects the second pair of deflectable contact arms to each other.

8. A portable electronic device spring clip as in claim 6 wherein the second pair of deflectable contact arms each comprise a raised protuberance forming a contact surface.

9. A display module mounting assembly for mounting a display module to a printed wiring board (PWB) in a portable electronic device, the mounting assembly comprising:
a framework comprising a spring clip mounting area; and
a portable electronic device spring clip as in claim 1 connected to the framework.

10. A display module mounting assembly for mounting a display module to a printed wiring board (PWB) in a portable electronic device, the mounting assembly comprising:
a framework comprising a spring clip mounting area; and
an electrically conductive spring clip connected to the framework at the spring clip mounting area,
wherein the spring clip comprises deflectable contact sections and a retention section, wherein the deflectable contact sections are adapted to electrically contact the display module to the PWB, and wherein the retention section is adapted to clip onto the framework,
wherein the spring clip mounting area comprises at least one first recess for locating the retention section of the spring clip in the at least one first recess to thereby clip the spring clip onto the framework, and at least one second recess providing an open area within the framework for allowing the deflectable contact sections of the spring clip to deflect into when the deflectable contact sections make contact with the display module and the PWB.

11. A display module mounting assembly as in claim 10 wherein the retention section of the spring clip comprises:
a first retention section adapted to attach the spring clip to the framework; and
a second retention section adapted to be located at a top side of a metal cover frame of a display module of a portable electronic device.

12. A display module mounting assembly as in claim 10 wherein the deflectable contact sections of the spring clip comprises:
a first contact section adapted to electrically connect to a printed wiring board (PWB); and
a second contact section adapted to electrically connect to the metal cover frame of the display module

13. A display module mounting assembly as in claim 10 wherein the retention section comprises a retention lip sized and shaped to be located above a top surface of the display module when the display module is located in a receiving area of the framework.

14. A display module mounting assembly as in claim 10 wherein a first one of the deflectable contact sections comprises a first pair of deflectable contact arms.

15. A portable electronic device spring clip as in claim 14 wherein the contact arms each comprise a raised protuberance forming a contact surface.

16. A portable electronic device spring clip as in claim 14 wherein a second one of the deflectable contact sections comprises a second pair of deflectable contact arms.

17. A portable electronic device spring clip as in claim 16 wherein the second retention section comprises a retention lip sized and shaped to be located above a top surface of the display module when the display module is located in a receiving area of the framework, and wherein the retention lip connects the second pair of deflectable contact arms to each other.

18. A portable electronic device spring clip as in claim 16 wherein the second pair of deflectable contact arms each comprise a raised protuberance forming a contact surface.

19. A method of assembling a portable electronic device comprising:
clipping electrically conductive spring clips onto a framework;
inserting a display module into a receiving area of the framework, wherein the spring clips make electrical contact with the display module at the receiving area and form retention lips above a top surface of the display module; and
attaching the framework to a printed wiring board (PWB), wherein the display module is mechanically captured by the retention lips and contact arms of the spring clips, and wherein the spring clips make electrical contact with the PWB to thereby electrically connect the display module to the PWB.

20. A method as in claim 19 wherein, when the framework is attached to the PWB, first deflectable contact arms of the spring clips are deflected by the PWB, and wherein, when the spring clips make electrical contact with the display module at the receiving area, second deflectable contact arms of the spring clips are deflected by the display module.
